(19) United States
(12) Patent Application Publication
(10) Pub. No.: US 2009/0127670 A1
(43) Pub. Date: May 21, 2009

(54) SEMICONDUCTOR DEVICE, METHOD FOR MANUFACTURING THE SAME AND MASK PATTERN FOR MANUFACTURING THE SAME

(75) Inventor: Naoki MATSUNAGA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/267,881

(22) Filed: Nov. 10, 2008

(30) Foreign Application Priority Data
Nov. 12, 2007 (JP) 2007-293422

(51) Int. Cl. H01L 27/00; H01L 21/76; G03F 7/004

(52) U.S. Cl. 257/632; 430/5; 257/E27.001; 257/E21.54

(57) ABSTRACT

A semiconductor device includes: a semiconductor substrate; and an insulating layer formed on at least a main surface of the semiconductor substrate; wherein a contact hole is formed at the insulating layer so as to expose the main surface of the semiconductor substrate through the insulating layer so that a cross section of the contact hole parallel to the main surface of the semiconductor substrate is shaped rectangularly.

### CROSS-REFERENCE TO RELATED APPLICATIONS

This application is based upon and claims the benefit of priority from the prior Japanese Patent Application No. 2007-293422 filed on Nov. 12, 2007; the entire contents of which are incorporated herein by reference.

### BACKGROUND OF THE INVENTION

1. Field of the Invention

The present invention relates to a semiconductor device having a contact hole of rectangular cross section, a method for manufacturing the semiconductor device and a mask pattern for manufacturing the semiconductor device.

2. Description of the Related Art

In a conventional semiconductor device, an insulating layer is formed on a main surface of a semiconductor substrate, and some contact holes are formed at the insulating layer so that conductive layers are formed in the contact holes, thereby realizing the electric conduction between the semiconductor substrate and an external element.

The contact holes are formed as follows: First of all, a predetermined resist pattern is formed on the insulating layer by using the corresponding mask pattern and then, etching treatment is conducted for the insulating layer via the resist pattern as a mask. In this case, the mask pattern is formed so as to have the holes commensurate with the shapes of the cross sections of the contact holes. Generally, the holes of the mask pattern are shaped rectangularly. In this point of view, the contact holes should be formed so that the cross sections thereof are shaped rectangularly commensurate with the rectangular shapes of the holes of the mask pattern, but really shaped circularly due to the complex combination of the optical interference and reflection via the mask pattern.

Since the cross section of the circular contact hole becomes smaller than the cross section of the rectangular contact hole, the connection between the upper contact hole and the lower contact hole can not be realized under good condition due to the contact shift therebetween when a stack contact is formed. Therefore, when an upper conductive layer is formed in the upper contact and a lower conductive layer is formed in the lower contact, the upper conductive layer can not be electrically connected with the lower conductive layer under good condition so as to increase the contact resistance at the connection between the upper conductive layer and the lower conductive layer and thus, deteriorate the electric characteristics of an intended semiconductor device.

In view of the above-described problem, Reference 1 teaches that an additional conductive layer is provided between the upper contact hole and the lower contact hole so as to be parallel to the main surface of the semiconductor substrate. In this case, if the contact shift occurs, the contact resistance between the upper conductive layer formed in the upper contact hole and the lower conductive layer formed in the lower contact hole can not be increased with the additional conductive layer. In Reference 1, however, since the additional process of forming the additional conductive layer is required, the manufacturing process of the semiconductor device becomes complicated.

Moreover, Reference 2 teaches that the area of the opening of the lower contact hole to be contacted with the upper contact hole is enlarged so as to reduce the contact shift between the upper conductive layer formed in the upper contact hole and the lower conductive layer formed in the lower contact hole and thus, reduce the contact resistance between the upper conductive layer and the lower conductive layer. In this case, however, since the additional process of enlarging the opening of the lower contact hole is required, the manufacturing process of the semiconductor device becomes complicated. Moreover, if the opening of the lower contact hole is not enlarged sufficiently, the contact between the upper conductive layer and the lower conductive layer can not be realized sufficiently so that the contact resistance between the upper conductive layer and the lower conductive layer can not be reduced.

In References 3 and 4, the mask pattern for forming the contact holes is devised such that the rectangular supplemental patterns are formed at all of the corners of the rectangular main pattern, and such an attempt is made as forming the intended rectangular contact holes using the devised mask pattern. According to References 3 and 4, however, the intended rectangular contact holes can not be formed so that the contact resistance can not be reduced sufficiently.

[Reference 1] JP-A 08-298286 (KOKAI)

[Reference 2] JP-A 10-308448 (KOKAI)

[Reference 3] U.S. Pat. No. 5,707,765

[Reference 4] JP-A 2004-054052 (KOKAI)

### BRIEF SUMMARY OF THE INVENTION

An aspect of the present invention relates to a semiconductor device, including: a semiconductor substrate; and an insulating layer formed on at least a main surface of the semiconductor substrate; wherein a contact hole is formed at the insulating layer so as to expose the main surface of the semiconductor substrate through the insulating layer so that a cross section of the contact hole parallel to the main surface of the semiconductor substrate is shaped rectangularly.

Another aspect of the present invention relates to a semiconductor device, including: a semiconductor substrate; and a first insulating layer and a second insulating layer which are subsequently formed on at least a main surface of the semiconductor substrate; wherein a first contact hole and a second contact hole are formed at the first insulating layer and the second insulating layer through the first insulating layer and second insulating layer, respectively, so that a cross section of at least one of the first contact hole and the second contact hole parallel to the main surface of the semiconductor substrate is shaped rectangularly and is set larger than a cross section of the other of the first contact hole and the second contact hole.

Still another aspect of the present invention relates to a method for manufacturing a semiconductor device, including: forming an insulating layer on at least a main surface of the semiconductor substrate; and conducting etching treatment for the insulating layer via a mask pattern having a rectangular main pattern, first rectangular supplemental patterns respectively formed at corners of the main pattern and second supplemental patterns respectively formed at centers of sides of the main pattern to form a contact hole at the insulating layer so as to expose the main surface of the semiconductor substrate through the insulating layer so that a cross section of the contact hole parallel to the main surface of the semiconductor substrate is shaped rectangularly.

A further aspect of the present invention relates to a mask pattern, including: a rectangular main pattern; first rectangular supplemental patterns respectively formed at corners of the main pattern; and second supplemental patterns respectively formed at centers of sides of the main pattern.

### BRIEF DESCRIPTION OF THE DRAWINGS

FIG. 1 is a plan view schematically showing the shape of a mask pattern according to an embodiment.

FIG. 2 is an explanatory view schematically showing a method for manufacturing a semiconductor device according to a first (second) embodiment.

FIG. 3 is also an explanatory view schematically showing a method for manufacturing a semiconductor device according to the first (second) embodiment.

FIG. 4 is also an explanatory view schematically showing a method for manufacturing a semiconductor device according to the first embodiment.

FIG. 5 is also an explanatory view schematically showing a method for manufacturing a semiconductor device according to the first embodiment.

FIG. 6 is also an explanatory view schematically showing a method for manufacturing a semiconductor device according to the second embodiment.

FIG. 7 is also an explanatory view schematically showing a method for manufacturing a semiconductor device according to the second embodiment.

FIG. 8 is also an explanatory view schematically showing a method for manufacturing a semiconductor device according to the second embodiment.

FIG. 9 is also an explanatory view schematically showing a method for manufacturing a semiconductor device according to the second embodiment.

FIG. 10 is also an explanatory view schematically showing a method for manufacturing a semiconductor device according to the second embodiment.

FIG. 11 is a graph showing the cumulative probability of the contact resistance between the drain region and the conductive layer in the semiconductor device manufactured according to the first embodiment.

FIG. 12 is a graph showing the relation between the contact shift and the yield ratio in resistance of the stack contact I the semiconductor device manufactured according to the second embodiment.

### DETAILED DESCRIPTION OF THE INVENTION

Then, some embodiments will be described with reference to the drawings.

### (Mask Pattern)

First of all, a mask pattern to be used for forming contact holes of a semiconductor device will be described.

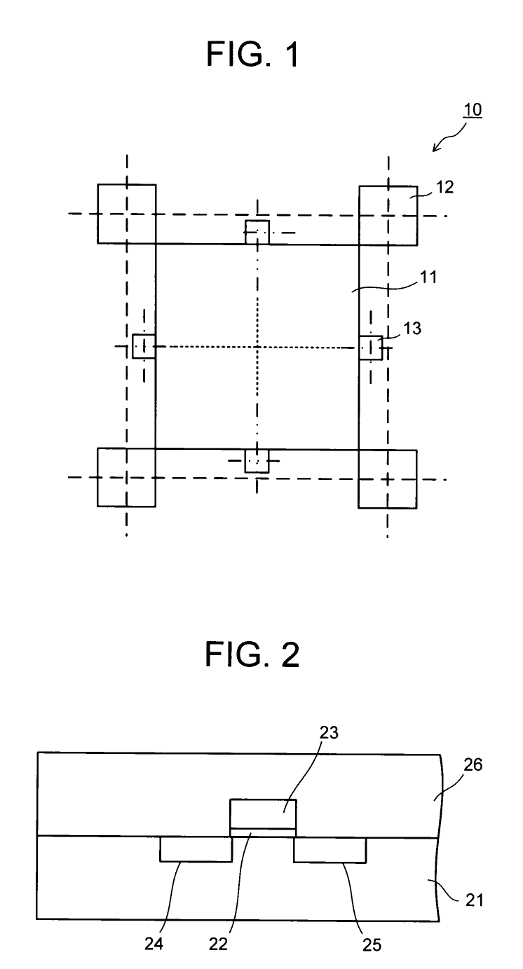

FIG. 1 is a plan view schematically showing the shape of a mask pattern according to an embodiment. In this embodiment, as shown in FIG. 1, the mask pattern 10 includes a rectangular main pattern 11 located at the center thereof, first supplemental patterns 12 respectively formed at the corners of the main pattern 11, and second supplemental patterns 13 respectively formed at the centers of the sides of the main pattern 11. The main pattern 11, the first supplemental patterns 12 and the second supplemental patterns 13 function as shutting out light so as to form the light shutting-out area.

The first supplemental patterns 12 has the same size as one another. The corner of each of the first supplemental patterns 12 is contacted with the corresponding corner of the main pattern 11. The sides of each of the first supplemental patterns 12 elongated from the corner thereof contacting with the corner of the main pattern 11 continue linearly from the sides of the main pattern 11 elongated from the corner thereof contacting with the corner of each of the first supplemental patterns 12. Then, the first supplemental patterns 12 are arranged so that the line segments formed between the centers of the first supplemental patterns 12 are set parallel to the sides of the main pattern 11.

The second supplemental patterns 13 has the same size as one another. The side of each of the second supplemental patterns 13 is contacted with the corresponding side of the main pattern 11. The center of the side of each of the second supplemental patterns 13 contacting with the corresponding side of the main pattern 11 is matched with the center of the corresponding side of the main pattern 11. Then, the second supplemental patterns 13 are arranged on the lines parallel to the center lines across the center of the main pattern 11. By utilizing the mask pattern shown in FIG. 1, the intended semiconductor device having the contact holes with the respective rectangular cross sections can be formed.

Therefore, since the cross section of the contact hole parallel to the main surface of the semiconductor substrate is shaped rectangularly, the contact area between the upper contact and the lower contact in the stack contact can be increased even though the contact shift between the upper contact hole and the lower contact hole occurs. In this point of view, when the upper conductive layer is formed in the upper contact hole and the lower conductive layer is formed in the lower contact hole, the contact resistance between the upper conductive layer and the lower conductive layer can not be increased due to the inherent large contact area between the upper contact hole and the lower contact hole. As a result, the electric characteristics of the semiconductor device can be maintained under good condition.

As described above, in References 3 and 4, such a mask pattern as including the main pattern 11 and the first supplemental pattern 12 is formed, but in this embodiment, the mask pattern 10 includes the second supplemental patterns 13 in addition to the main pattern 11 and the first supplemental pattern 12. In this point of view, the mask pattern 10 in this embodiment is different from the mask pattern in References 3 and 4. The intended rectangular contact holes can be formed by using the mask pattern as shown in this embodiment. The mask pattern can be considered by the inventor through enormous quantity of experiments and trials.

In FIG. 1, the main pattern 11, the first supplemental patterns 12 and the second supplemental patterns 13 are formed in square shape, but may be in any rectangular shape depending on the condition of photolithography and the shapes and sizes of the intended contact holes.

Suppose that the length of the side of the main pattern 11 is defined as “a” and the length of the side of the first supplemental pattern 12 is defined as “b”, it is desired that the length “b”, is set within a range of one-third to one-half of the length “a”. In this case, the cross sectional area of the contact hole can be easily formed as designed. Herein, if the length “b” is set much smaller than the length “a”, the function of the first supplemental patterns 12 can not be exhibited so that the cross section of the contact hole may be shaped circular or elliptical.

Alternatively, suppose that the length of the side of the second supplemental pattern 12 is defined as “c”, it is desired that the length “c” is set within a range of one-sixth to one-fifth of the length “a”. In this case, the cross sectional area of the contact hole can be easily formed as designed. Herein, if the length “c” is set much smaller than the length “a”, the function of the second supplemental patterns 13 can not be exhibited so that the cross section of the contact hole may be shaped circular or elliptical.

### (Semiconductor Device)

Then, a method for manufacturing a semiconductor device using the mask pattern will be described. In this embodiment, a method for manufacturing a normal MOS transistor as the semiconductor device will be described.

FIGS. 2 to 5 are explanatory views showing the manufacturing method of the semiconductor device (MOS transistor) according to a first embodiment. As shown in FIG. 2, a gate electrode 23 is formed on a semiconductor substrate 21 made of silicon or the like via a gate insulating film 22. Then, a source region 24 and a drain region 25 are formed at the surface region of the substrate 21 by means of ion implantation. Then, an insulating layer 26 is formed on the main surface of the substrate 21.

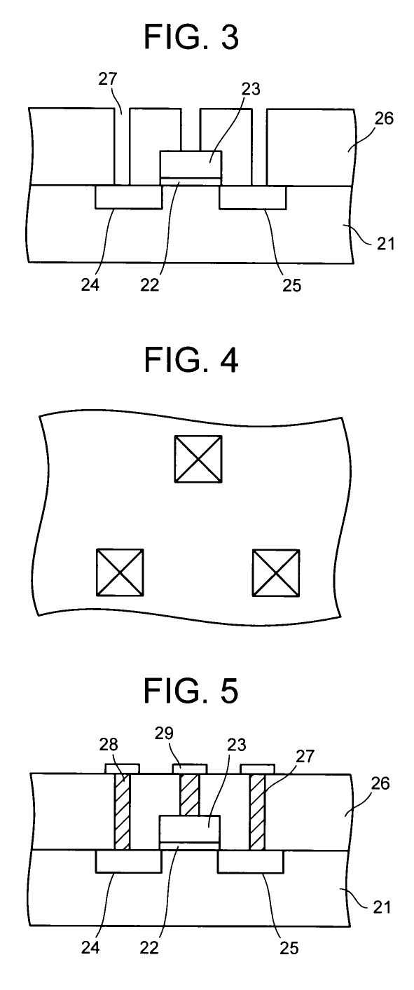

Then, a resist (not shown) is applied on the insulating layer 26 and the mask pattern 10 as shown in FIG. 1 is disposed on the resist so as to form a predetermined resist pattern by means of photolithography. Then, RIE is conducted via the resist pattern so that the insulating layer 26 is etched in the thickness direction thereof until the surface of the substrate 21 is exposed, thereby forming a contact hole 27 through the gate electrode 23, the source region 24 and the drain region 25 as shown in FIG. 3. Herein, the shape of the cross section of the contact hole 27 parallel to the main surface of the substrate 21 (i.e., the plane shape as view from the above) becomes rectangular commensurate with the patterned shape of the mask pattern 10 as shown in FIG. 4.

Then, as shown in FIG. 5, after a barrier metal layer (not shown) is formed on the inner wall of the contact hole 27 as occasion demands, a conductive layer 28 is formed in the contact hole 27 by means of CVD or the like, and pads (metal wire) 29 are formed to complete the intended semiconductor device (MOS transistor).

In FIG. 4, the cross section of the contact hole 27 is shaped perfect square, but may not. For example, when the length of the side of the contact hole 27 is defined as “h1” and the length of the linear portion of the side of the contact hole 27 is defined as “h2” in the cross section of the contact hole 27, the ratio of h2/h1 may be set to 0.8 or more. In this case, the corners of the contact hole 27 are curved to some degrees so that the deposit of the barrier metal layer and/or the conductive layer 28 at the corners of the contact hole 27 can be improved.

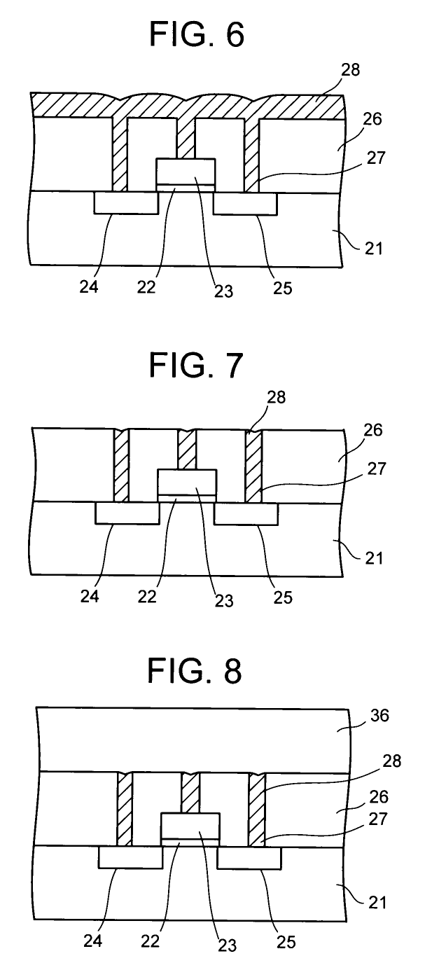

FIGS. 6 to 10 are explanatory views showing the manufacturing method of the semiconductor device (MOS transistor) according to a second embodiment. Like or corresponding constituent components are designated by the same reference numerals throughout FIGS. 2 to 10.

First of all, as shown in FIG. 2, the gate electrode 23 is formed on the semiconductor substrate 21 made of silicon or the like via the gate insulating film 22. Then, the source region 24 and the drain region 25 are formed at the surface region of the substrate 21 by means of ion implantation. Then, the insulating layer 26 is formed on the main surface of the substrate 21.

Then, a resist (not shown) is applied on the insulating layer 26 and the mask pattern 10 as shown in FIG. 1 is disposed on the resist so as to form a predetermined resist pattern by means of photolithography. Then, RIE is conducted via the resist pattern so that the insulating layer 26 is etched in the thickness direction thereof until the surface of the substrate 21 is exposed, thereby forming the contact hole 27 through the gate electrode 23, the source region 24 and the drain region 25 as shown in FIG. 3.

Then, as shown in FIG. 6, the conductive layer 28 is formed in the contact hole 27 by means of CVD or the like so as to embed the contact hole 27, and then, etched back so as to remain in the contact hole 27 (refer to FIG. 7).

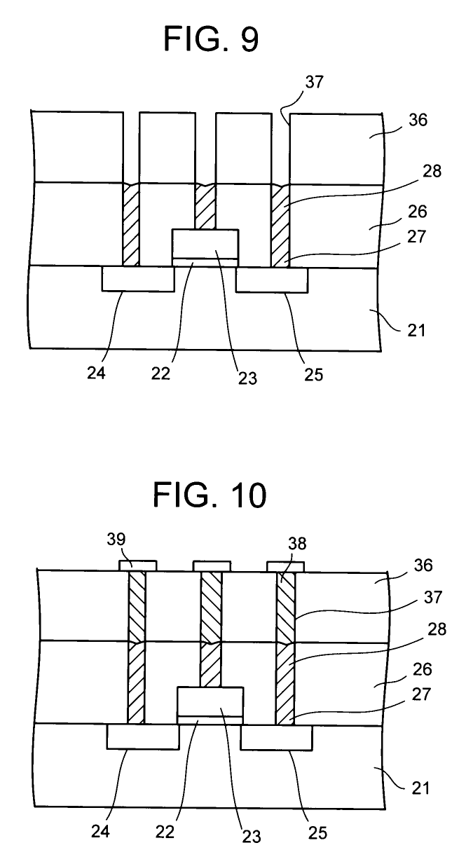

Then, as shown in FIG. 8, an interlayer insulating layer 36 is formed on the insulating layer 26, and then, a resist (not shown) is applied on the interlayer insulating layer 36. Thereafter, the mask pattern 10 as shown in FIG. 1 is disposed on the resist so as to form a predetermined resist pattern by means of photolithography. Then, RIE is conducted via the resist pattern so that the interlayer insulating layer 36 is etched in the thickness direction thereof until the surface of the conductive layer 28 is exposed, thereby forming a contact hole 37 (refer to FIG. 9). The contact hole 27 and the contact hole 37 constitute a stack contact.

Then, as shown in FIG. 10, after a barrier metal layer (not shown) is formed on the inner wall of the contact hole 37 as occasion demands, a metal plug 38 is formed in the contact hole 37 by means of CVD or the like, and a metal wire 39 is formed so as to be electrically connected with the metal plug 38 to complete the intended semiconductor device (MOS transistor).

In this embodiment, since the mask pattern 10 as shown in FIG. 1 is employed in the formation of the contact holes 27 and 37, the shapes of the cross sections of the contact holes 27 and 37 become rectangular as shown in FIG. 4. In the case that the stack contact is formed as in this embodiment, since the contact area between the conductive layer 28 located downward and the metal plug 38 located upward can be increased, the contact resistance between the conductive layer 28 and the metal plug 38 can be reduced so that the electric characteristics of the semiconductor device can be maintained under good condition.

In this embodiment, both of the contact holes 27 and 37 are formed rectangularly, but either of the contact hole 27 or 37 may be formed rectangularly. In the latter case, the contact area between the conductive layer 28 and the metal plug 38 can be also increased so that the contact resistance between the conductive layer 28 and the metal plug 38 can be reduced and thus, the electric characteristics of the semiconductor device can be maintained under good condition.

In this embodiment, the cross sectional area of one of the contact holes 27 and 37 may be set larger than the cross sectional area of the other of the contact holes 27 and 37. In this case, the contact area between the conductive layer 28 and the metal plug 38 can be increased so that the contact resistance between the conductive layer 28 and the metal plug 38 can be reduced and thus, the electric characteristics of the semiconductor device can be maintained under good condition.

### EXAMPLES

### Example 1

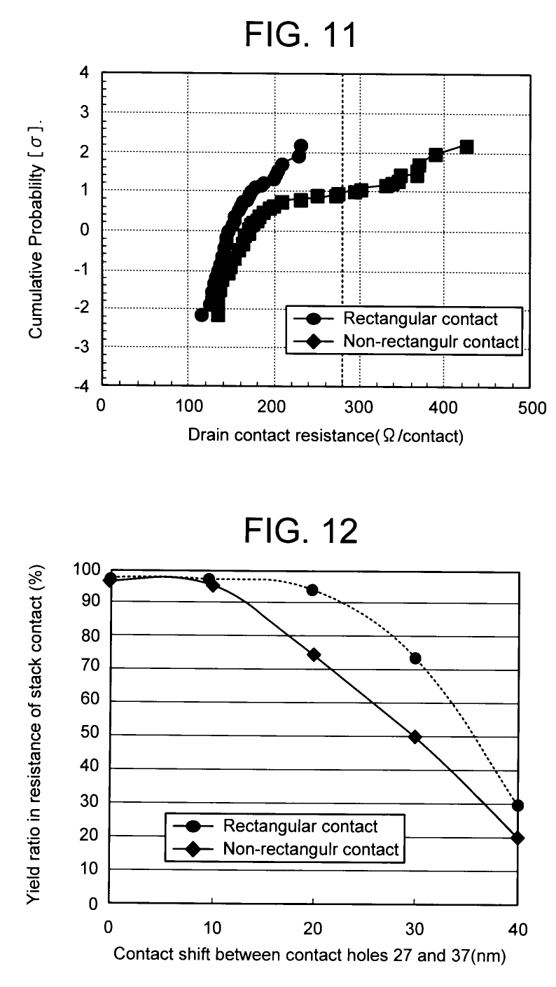

FIG. 11 is a graph showing the cumulative probability of the contact resistance between the drain region 25 and the conductive layer 28 in the semiconductor device manufactured according to the first embodiment. In FIG. 11, the cumulative probability of the contact resistance obtained by using a conventional mask pattern as taught in Reference 1 is comparatively shown.

In the case that the contact hole with rectangular cross section is formed according to the embodiment, as apparent from FIG. 11, the cumulative probability of the contact resistance is increased within a region of low contact resistance. In the case that the contact hole with not rectangular (circular) cross section is formed according to the comparative embodiment, the cumulative probability of the contact resistance is spread over a wide range. It is apparent, therefore, that the contact area between the drain region 25 and the conductive layer 28 can be increased so as to reduce the contact resistance between the drain region 25 and the conductive layer 28 by forming the rectangular contact hole according to the embodiment.

### Example 2

FIG. 12 is a graph showing the relation between the contact shift and the yield ratio in resistance of the stack contact in the semiconductor device manufactured according to the second embodiment. In FIG. 12, the relation between the contact shift and the yield ratio in resistance of the stack contact in the semiconductor device manufactured by using the conventional mask pattern as taught in Reference 1 is comparatively shown. The size of the contact hole is designed to 100 nm and the contact resistance is designed to 20Ω. The allowance margin is set within a range of ±15% on the design.

In the case that the contact hole with rectangular cross section is formed according to the embodiment, as apparent from FIG. 12, since the contact area between the upper conductive layer and the lower conductive layer is increased even though the contact shift between the upper contact hole and the lower contact hole occurs, the yield ratio in resistance of the stack contact is increased so that the allowance margin of the contact shift is increased. In the case that the contact hole with not rectangular (circular) cross section is formed according to the comparative embodiment, the yield ratio in resistance of the stack contact is not much increased.

It is apparent, therefore, that the yield ratio in resistance of the stack contact can be increased by forming the rectangular contact hole according to the embodiment.

Although the present invention was described in detail with reference to the above examples, this invention is not limited to the above disclosure and every kind of variation and modification may be made without departing from the scope of the present invention.

In the embodiments, explanation is centered on the normal MOS transistor, but the present invention can be applied for another semiconductor device such as a stacked semiconductor memory requiring the contact holes.

What is claimed is:

1. A semiconductor device, comprising:
a semiconductor substrate; and
an insulating layer formed on at least a main surface of the semiconductor substrate;
wherein a contact hole is formed at the insulating layer so as to expose the main surface of the semiconductor substrate through the insulating layer so that a cross section of the contact hole parallel to the main surface of the semiconductor substrate is shaped rectangularly.

2. The semiconductor device as set forth in claim 1,
wherein in the cross section of the contact hole, corners of the contact hole are curved so that a ratio of a length of a linear portion of each side of the contact hole to a length of each side of the contact hole is set to 0.8 or more.

3. A semiconductor device, comprising:
a semiconductor substrate; and
a first insulating layer and a second insulating layer which are subsequently formed on at least a main surface of the semiconductor substrate;
wherein a first contact hole and a second contact hole are formed at the first insulating layer and the second insulating layer through the first insulating layer and second insulating layer, respectively, so that a cross section of at least one of the first contact hole and the second contact hole parallel to the main surface of the semiconductor substrate is shaped rectangularly and is set larger than a cross section of the other of the first contact hole and the second contact hole.

4. The semiconductor device as set forth in claim 3,
wherein cross sections of both of the first contact hole and the second contact hole parallel to the main surface of the semiconductor substrate are shaped rectangularly and the cross section of the first contact hole or the second contact hole is set larger than the cross section of the second contact hole or the first contact hole.

5. A method for manufacturing a semiconductor device, comprising:
forming an insulating layer on at least a main surface of the semiconductor substrate; and
conducting etching treatment for the insulating layer via a mask pattern having a rectangular main pattern, first rectangular supplemental patterns respectively formed at corners of the main pattern and second supplemental patterns respectively formed at centers of sides of the main pattern to form a contact hole at the insulating layer so as to expose the main surface of the semiconductor substrate through the insulating layer so that a cross section of the contact hole parallel to the main surface of the semiconductor substrate is shaped rectangularly.

6. The manufacturing method as set forth in claim 5,
wherein the first supplemental patterns has the same size as one another.

7. The manufacturing method as set forth in claim 5,
wherein a corner of each of the first supplemental patterns is contacted with a corresponding corner of the main pattern and sides of each of the first supplemental patterns elongated from a corner thereof contacting with the corner of the main pattern continue linearly from the sides of the main pattern elongated from the corner thereof contacting with the corner of each of the first supplemental patterns, and the first supplemental patterns are arranged so that line segments formed between centers of the first supplemental patterns are set parallel to the sides of the main pattern.

8. The manufacturing method as set forth in claim 5,
wherein the second supplemental patterns has the same size as one another.

9. The manufacturing method as set forth in claim 5,
wherein a side of each of the second supplemental patterns is contacted with a corresponding side of the main pattern and a center of the side of each of the second supplemental patterns contacting with the corresponding side of the main pattern is matched with a center of the corresponding side of the main pattern, and the second supplemental patterns are arranged on lines parallel to center lines across a center of the main pattern.

10. The manufacturing method as set forth in claim 5,
wherein when a length of the side of the main pattern is defined as “a” and a length of a side of each of the first supplemental patterns is defined as “b”, the length “b” is set within a range of one-third to one-half of the length “a”.

11. The manufacturing method as set forth in claim 5,
wherein when a length of the side of the main pattern is defined as “a” and a length of a side of the second supplemental pattern is defined as “c”, the length “c” is set within a range of one-sixth to one-fifth of the length “a”.

12. A method for manufacturing a semiconductor device, comprising:
forming a first insulating layer on at least a main surface of the semiconductor substrate;
conducting etching treatment for the first insulating layer via a mask pattern having a rectangular main pattern, first rectangular supplemental patterns respectively formed at corners of the main pattern and second supplemental patterns respectively formed at centers of sides of the main pattern to form a first contact hole at the first insulating layer so as to expose the main surface of the semiconductor substrate through the first insulating layer so that a cross section of the first contact hole parallel to the main surface of the semiconductor substrate is shaped rectangularly;
forming a second insulating layer on the first insulating layer; and
conducting the etching treatment for the second insulating layer via the mask pattern to form a second contact hole communicated with the first contact hole so that a cross section of the second contact hole parallel to the main surface of the semiconductor substrate is shaped rectangularly.

13. The manufacturing method as set forth in claim 12,
wherein the first supplemental patterns has the same size as one another.

14. The manufacturing method as set forth in claim 12,
wherein a corner of each of the first supplemental patterns is contacted with a corresponding corner of the main pattern and sides of each of the first supplemental patterns elongated from a corner thereof contacting with the corner of the main pattern continue linearly from the sides of the main pattern elongated from the corner thereof contacting with the corner of each of the first supplemental patterns, and the first supplemental patterns are arranged so that line segments formed between centers of the first supplemental patterns are set parallel to the sides of the main pattern.

15. The manufacturing method as set forth in claim 12,
wherein the second supplemental patterns has the same size as one another.

16. The manufacturing method as set forth in claim 12,
wherein a side of each of the second supplemental patterns is contacted with a corresponding side of the main pattern and a center of the side of each of the second supplemental patterns contacting with the corresponding side of the main pattern is matched with a center of the corresponding side of the main pattern, and the second supplemental patterns are arranged on lines parallel to center lines across a center of the main pattern.

17. The manufacturing method as set forth in claim 12,
wherein when a length of the side of the main pattern is defined as “a” and a length of a side of each of the first supplemental patterns is defined as “b”, the length “b” is set within a range of one-third to one-half of the length “a”.

18. The manufacturing method as set forth in claim 12,
wherein when a length of the side of the main pattern is defined as “a” and a length of a side of the second supplemental pattern is defined as “c”, the length “c” is set within a range of one-sixth to one-fifth of the length “a”.

19. A mask pattern, comprising:
a rectangular main pattern;
first rectangular supplemental patterns respectively formed at corners of the main pattern; and
second supplemental patterns respectively formed at centers of sides of the main pattern.

20. The mask pattern as set forth in claim 19,
wherein when a length of the side of the main pattern is defined as “a” and a length of a side of each of the first supplemental patterns is defined as “b”, the length “b”, is set within a range of one-third to one-half of the length “a”; and
wherein a length of a side of the second supplemental pattern is defined as “c”, the length “c” is set within a range of one-sixth to one-fifth of the length “a”.
